(19) United States
(12) Patent Application Publication
(10) Pub. No.: US 2026/0112566 A1
(43) Pub. Date: Apr. 23, 2026

(54) High Angle, Low Energy Ion Beam Extraction with Tunable Extraction Electrodes

(71) Applicant: Applied Materials, Inc., Santa Clara, CA (US)

(72) Inventors: Alexander S. Perel, Danvers, MA (US); Alexandre Likhanskii, Middleton, MA (US)

(21) Appl. No.: 18/924,732

(22) Filed: Oct. 23, 2024

(51) Int. Cl. H01J 37/08; H01L 21/263

(52) U.S. Cl. CPC H01J 37/08; H10P 34/40

(57) ABSTRACT

A system and method for improving the operating range of an ion source for the extraction of an ion beam with a high tilt angle are disclosed. The system includes a semiconductor processing system that includes an extraction plate having an extraction aperture that is not parallel to the surface of the workpiece. An extraction electrode is disposed outside the ion source near the extraction aperture to attract ions toward the workpiece. The voltage applied to this extraction electrode may be varied to affect the extracted ion beam. The extraction aperture may comprise an elongated slot and the extraction electrode may be separated into two pieces, one on each side of the elongated slot. In this way, the two pieces of the extraction electrode may be independently biased. This feature may also allow variation of the tilt angle.

### FIELD

Embodiments of the present disclosure relate to systems and methods for improving high angle, low energy ion beam extraction, and more specifically the use of tunable voltages applied to the extraction electrode.

### BACKGROUND

Semiconductor processing includes a plurality of different processes, such as etching, deposition, and implanting. In some of these processes, an ion beam is directed toward the workpiece to implant ions in the workpiece or etch the workpiece. In some embodiments, it may be desirable to have a high tilt angle ion beam that strikes the workpiece. Tilt angle is defined as the angle between the ion beam and a line that is perpendicular to the surface of the workpiece. Thus, a 0° tilt angle represents an ion beam that is normal to the surface of the workpiece, with 90° representing an ion beam that is parallel to the surface of the workpiece.

Generating high tilt angle ion beams may be difficult and may be created using a combination of features. One such feature is an ion source that includes an extraction plate that is not parallel to the surface of the workpiece. Additionally, the power supplied to the ion source and the extraction voltage also determine the tilt angle of the ion beam.

In some systems, there is a limited operating range that may be used to produce a focused ion beam with the desired tilt angle. For example, for a certain RF power level that is applied to the ion source, there may be a narrow range of extraction voltages that result in a focused ion beam with the desired tilt angle. Similarly, for a certain extraction voltage, there may be a narrow range of RF power levels that result in the desired ion beam.

Therefore, it would be beneficial if there were a system and method for improving the operating range for extraction of ion beams with a high tilt angle. Further, it would be advantageous if the tilt angles of the ion beam could easily be adjusted.

### SUMMARY

A system and method for improving the operating range of an ion source for the extraction of an ion beam with a high tilt angle are disclosed. The system includes a semiconductor processing system that includes an extraction plate having an extraction aperture that is not parallel to the surface of the workpiece. An extraction electrode is disposed outside the ion source near the extraction aperture to attract ions toward the workpiece. The voltage applied to this extraction electrode may be varied to affect the extracted ion beam. The extraction aperture may comprise an elongated slot and the extraction electrode may be separated into two pieces, one on each side of the elongated slot. In this way, the two pieces of the extraction electrode may be independently biased. This feature may also allow variation of the tilt angle.

According to one embodiment, a semiconductor processing system is disclosed. The semiconductor processing system comprises a workpiece holder; an ion source to generate a ribbon ion beam which is larger in a width direction than in a height direction, the ion source comprising an ion source chamber including an extraction plate having a slanted portion with an extraction aperture, wherein the slanted portion is not parallel to the workpiece holder when the workpiece holder is in a processing position; an extraction electrode disposed outside the extraction aperture disposed between the extraction plate and the workpiece holder; and an electrode power supply to bias the extraction electrode at a different voltage from the workpiece holder and the ion source chamber. In some embodiments, a voltage applied to the extraction electrode by the electrode power supply is between -10,000V and 2000V. In some embodiments, the extraction electrode comprises a single component having an opening such that the ribbon ion beam passes therethrough. In some embodiments, the extraction electrode comprises a first extraction electrode portion and a second extraction electrode portion located on opposite sides of the extraction aperture in the height direction. In some embodiments, at least one power supply is used to create a voltage differential between the ion source chamber and the workpiece holder, wherein the voltage differential is referred to as an extraction voltage. In some embodiments, an RF antenna is in communication with at least one chamber wall of the ion source chamber, and a RF power supply to supply an RF power to the RF antenna.

According to another embodiment, a method of operating the semiconductor processing system described above is disclosed. The method comprises selecting an RF power to apply to the RF antenna; selecting an extraction voltage; and varying an output voltage of the electrode power supply until a focused ion beam is extracted from the extraction aperture.

According to another embodiment, a semiconductor processing system is disclosed. The semiconductor processing system comprises a workpiece holder; an ion source to generate a ribbon ion beam which is larger in a width direction than in a height direction, the ion source comprising an ion source chamber including an extraction plate having a slanted portion with an extraction aperture, wherein the slanted portion is not parallel to the workpiece holder when the workpiece holder is in a processing position; an extraction electrode disposed outside the extraction aperture disposed between the extraction plate and the workpiece holder, the extraction electrode comprising a first extraction electrode portion and a second extraction electrode portion located on opposite sides of the extraction aperture in the height direction; a first electrode power supply to bias the first extraction electrode portion; and a second electrode power supply to bias the second extraction electrode portion. In some embodiments, a voltage applied to the first extraction electrode portion by the first electrode power supply is between -10,000V and 2000V. In some embodiments, a voltage applied to the second extraction electrode portion by the second electrode power supply is between -10,000V and 2000V. In some embodiments, at least one power supply is used to create a voltage differential between the ion source chamber and the workpiece holder, wherein the voltage differential is referred to as an extraction voltage. In certain embodiments, an RF antenna is in communication with at least one chamber wall of the ion source chamber, and a RF power supply to supply an RF power to the RF antenna.

According to another embodiment, a method of operating the semiconductor processing system described above is disclosed. The method comprises selecting an RF power to apply to the RF antenna; selecting an extraction voltage; and varying output voltages of the first electrode power supply and the second electrode power supply until a focused ion beam is extracted from the extraction aperture. In some embodiments, the varying also adjusts a mean angle of the focused ion beam.

In certain embodiments, the output voltages of the first electrode power supply and the second electrode power supply are maintained at a same voltage as the ribbon ion beam is being focused, and the method further comprises measuring a mean angle of the focused ion beam; and creating a voltage differential between the first extraction electrode portion and the second extraction electrode portion to adjust the mean angle to achieve a desired tilt angle.

In some embodiments, the method comprises measuring a mean angle of the ribbon ion beam; and creating a voltage differential between the first extraction electrode portion and the second extraction electrode portion to adjust the mean angle to achieve a desired tilt angle.

### BRIEF DESCRIPTION OF THE FIGURES

For a better understanding of the present disclosure, reference is made to the accompanying drawings, which are incorporated herein by reference and in which:

FIG. 1 is a semiconductor processing system in accordance with one embodiment;

FIG. 2 is a semiconductor processing system in accordance with another embodiment;

FIG. 3 shows a view of a ribbon ion beam as it strikes the workpiece; and

FIGS. 4A-4B show an ion beam with a large spread and a focused ion beam, respectively.

### DETAILED DESCRIPTION

As noted above, the present system may be used to improve the operating range for the ion source associated with an ion beam extracted at a high tilt angle. In this disclosure, a high tilt angle refers to a tilt angle of between 40° and 89°. In certain embodiments, a high tilt angle may be defined as between 40° and 65°. As noted above, the tilt angle is referenced to a line that is perpendicular to the surface of the workpiece.

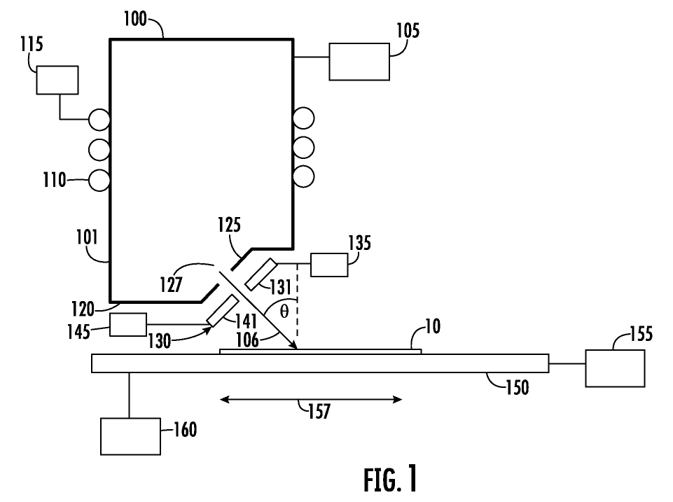

FIG. 1 shows a first embodiment of a semiconductor processing system when the workpiece holder 150 is in the processing position. The semiconductor processing system comprises an ion source, which includes an ion source chamber 100, comprised of a plurality of chamber walls 101. In certain embodiments, one or more of these chamber walls 101 may be constructed of a dielectric material, such as quartz. An RF antenna 110 may be disposed on one or more exterior surfaces of the dielectric walls. The RF antenna 110 may be powered by a RF power supply 115. The energy delivered to the RF antenna 110 is radiated within the ion source chamber 100 to ionize a feed gas, which is introduced via gas inlet. The amount of power supplied by the RF power supply 115 to the ion source chamber 100 may be referred to simply as the RF power.

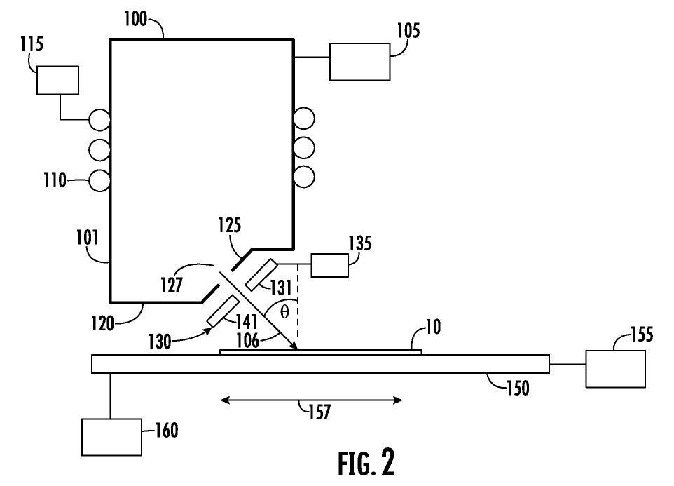

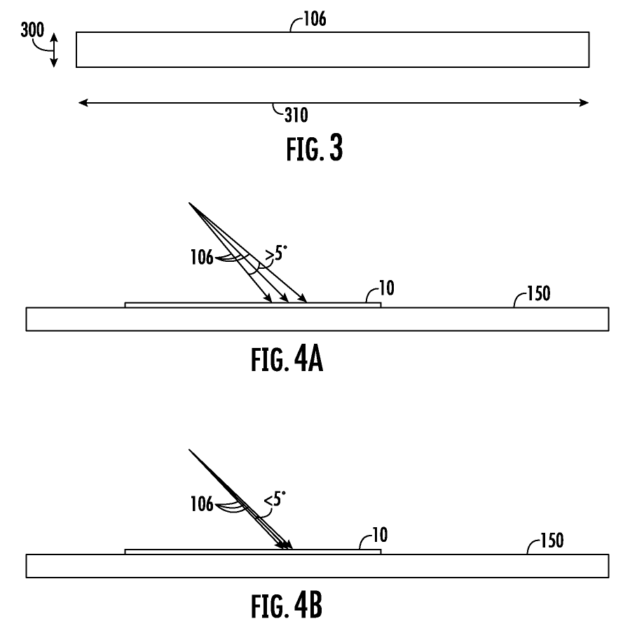

One chamber wall, referred to as the extraction plate 120 includes an extraction aperture 127 through which an ion beam 106 may exit the ion source chamber 100. The extraction plate 120 may include a portion that is parallel to the surface of the workpiece, and a slanted portion 125 that is slanted with respect to the surface of the workpiece. In other words, the slanted portion 125 is not parallel to the surface of the workpiece holder 150 when the workpiece holder 150 is in the processing position. The slanted portion is tilted about a line that extends in the width direction (which is defined as the direction perpendicular to the surface of the page in FIG. 1). The angle of this slant may vary and may be between 30° and 70°, which is not limited by this disclosure. The extraction aperture 127 may be located in the slanted portion 125. The extraction aperture 127 may be much wider in the width direction than the height direction (which is orthogonal to the width direction and parallel to the slanted portion 125) and may be referred to as an elongated slot. The ion beam 106 extracted through an extraction aperture 127 having these characteristics may be referred to as a ribbon ion beam. A representative ribbon ion beam is shown in FIG. 3, wherein the height 300 is much smaller than the width 310. Note that in FIGS. 1-2, the width 310 extends into the page, while the height 300 is in the left-right direction when the ribbon ion beam strikes the workpiece 10. Further, the ion beam 106 may have a high tilt angle (θ) relative to the workpiece 10. Note that all ion beamlets in the ion beam 106 exiting the extraction aperture 127 do not have the same high tilt angle. Rather, the phrase “ion beam having a high tilt angle” is meant to denote an ion beam where there are a plurality of beamlets having a distribution of tilt angles, having a mean tilt angle and wherein 90% of the beamlets have a tilt angle that is within ±5° of this mean tilt angle. The mean tilt angle may be between 40° and 89°. In certain embodiments, the mean tilt angle may be defined as between 40° and 65°. This distribution of angles of the plurality of beamlets may be referred to as the spread of the ion beam 106. An ion beam wherein 90% of the beamlets have a spread of less than or equal to ±5° is said to be a focused ion beam. A ribbon ion beam having a large spread (unfocused) is shown in FIG. 4A, while a focused ion beam is shown in FIG. 4B. FIG. 4A-4B show the ion beam 106 in the same orientation as is shown in FIGS. 1-2.

Some of the chamber walls and the extraction plate 120 may be constructed of an electrically conductive material, such as titanium, tantalum or another metal. Further, the extraction aperture 127 may be wider in the width direction than the diameter of the workpiece 10. The chamber walls and extraction plate 120 may be biased using extraction voltage power supply 105. In other embodiments, these components may be grounded and extraction voltage power supply 105 may not be used.

Outside the extraction aperture 127 is an extraction electrode 130. The extraction electrode 130 is positioned between the slanted portion 125 of the extraction plate 120 and the workpiece 10. The extraction electrode 130 may be parallel to the slanted portion 125 of the extraction plate 120 near the extraction aperture 127. The extraction electrode 130 may be between 2 and 20 mm from the slanted portion 125. The extraction electrode 130 may include two portions; a first extraction electrode portion 131 that is disposed on one side of the elongated slot in the height direction; and a second extraction electrode portion 141 that is disposed on the opposite side of the elongated slot in the height direction. In this embodiment, the first extraction electrode portion 131 and the second extraction electrode portion 141 are independently biased. The first extraction electrode portion 131 is biased using the first electrode power supply 135. The second extraction electrode portion 141 is biased using second electrode power supply 145. In some embodiments, the voltage output from one of the electrode power supplies may be referenced to the output of the other electrode power supply so as to provide a voltage differential between the two portions. In other embodiments, both electrode power supplies may be referenced to the same voltage, such as ground.

In this embodiment, the extraction electrode 130 may be biased independently from the ion source chamber 100 and the workpiece holder 150 using first electrode power supply 135 and second electrode power supply 145. The voltage applied to the two portions of the extraction electrode 130 may each be between, for example, -10,000V and +2500V, although other voltages may be used.

In addition, there is a workpiece holder 150. The workpiece holder 150 may be disposed proximate the extraction aperture 127. For example, the workpiece holder 150 may be between 0 and 50 mm from the parallel portion of the extraction plate 120 when it is in the processing position. In certain embodiments, the workpiece holder 150 may be within about 25 mm of the parallel portion.

A workpiece 10 may be disposed on the workpiece holder 150. The workpiece holder 150 is scanned using a scan motor 160, which moves in the scanning direction 157. Thus, the workpiece holder 150 is configured so that there is relative movement between the ion beam 106 and the workpiece holder 150.

The workpiece holder 150 may be biased using a workpiece bias power supply 155. In other embodiments, the workpiece holder 150 may be grounded. The difference between the voltage supplied to the ion source chamber 100 and the voltage supplied to the workpiece holder 150 is referred to as the extraction voltage. The desired extraction voltage may be achieved in different ways. For example, the workpiece holder 150 may be grounded, while the extraction voltage power supply 105 may supply a positive voltage to the ion source chamber 100. In another configuration, the ion source chamber 100 may be grounded and the workpiece bias power supply 155 may supply a negative voltage to the workpiece holder 150. Further, in other configurations, both components may be biased. In other words, there are one or more power supplies that are used to create a voltage differential, referred to as the extraction voltage, between the ion source chamber 100 and the workpiece holder 150. Typically, the extraction voltage may be between 500V and 3000V. Further, the extraction voltage is typically pulsed and may have an adjustable duty cycle. However, in other embodiments, the extraction voltage may be constant.

Note that there are no other components between the extraction plate 120 and the workpiece holder 150, except the extraction electrode 130. Further, note that it is the extraction voltage that attracts the ions from within the ion source chamber 100 toward the workpiece holder 150.

FIG. 2 shows a second embodiment of the semiconductor processing system when the workpiece holder 150 is in the processing position. Similar components have been given identical reference numbers. The ion source is as described above. In this embodiment, the first extraction electrode portion 131 and the second extraction electrode portion 141 are electrically connected such that both are at a common voltage. The voltage applied to both portions of the extraction electrode 130 may be supplied by first electrode power supply 135. Second electrode power supply 145 may be omitted in this embodiment. In certain embodiments, the first extraction electrode portion 131 and the second extraction electrode portion 141 may be physically connected, such that the extraction electrode 130 is a single component having an aperture therein to allow the ion beam 106 to pass.

These semiconductor processing systems have many uses. First, the tunability of the voltage applied to the extraction electrode 130 allows a wider operating range. Thus, in one example, the user may select a desired RF power to apply to the RF antenna 110 and a desired extraction voltage. Based on these two values, the output voltages of the electrode power supplies may be varied such that the voltage or voltages applied to the extraction electrode 130 achieve a focused ion beam. This may be achieved using the systems described in FIG. 1 or FIG. 2.

In another example, it may be desirable to modify the tilt angle. To do this, the system of FIG. 1 may be used. By applying a voltage differential between the first extraction electrode portion 131 and the second extraction electrode portion 141, the tilt angle of the ion beam 106 may be modified. Specifically, if the voltage applied to the second extraction electrode portion 141 by the second electrode power supply 145 is more negative than the voltage applied to first extraction electrode portion 131 by the first electrode power supply 135, the tilt angle of the ion beam 106 may be decreased. Conversely, if the voltage applied to the first extraction electrode portion 131 is more negative than the voltage applied to the second extraction electrode portion 141, the tilt angle of the ion beam 106 may be increased.

In certain embodiments, both of these operations may be performed concurrently or sequentially. For example, in a third example, an extraction voltage and an RF power may be selected and applied to the system. The voltage applied to the first extraction electrode portion 131 and the second extraction electrode portion 141 may be maintained at the same voltage and varied to achieve a focused ion beam, as described above. After this is complete, the mean angle of the focused ion beam may then be measured. If the mean angle is different from the desired tilt angle, a voltage differential is then created between the first extraction electrode portion 131 and the second extraction electrode portion 141 to achieve the desired tilt angle. In another embodiment, the voltage applied to the first extraction electrode portion 131 and the second extraction electrode portion 141 is varied simultaneously so that both the focus and mean angle are adjusted at the same time.

The embodiments described above in the present application may have many advantages.

First, as described above, these systems are used to create an ion beam having a high tilt angle. In traditional systems, to achieve a focused ion beam for a given extraction voltage, the range of RF power that is applied to the RF antenna 110 is limited. If the RF power is too low, the ion beam 106 is overfocused, and does not achieve the desired spread. If the RF power is too high, the ion beam 106 is underfocused, and again does not achieve the desired spread. By incorporating an extraction electrode 130 that is independently biased, it is possible to achieve a focused ion beam using a wider range of extraction voltages and RF powers. In one test, it was found that a traditional system achieves a focused beam for an extraction voltage of 1750V when the RF power is about 1200W. By using the independently biased extraction electrode 130, it is possible to achieve a focused ion beam for all RF powers between about 800W and 1800W. In other words, the RF power may be increased by 50% or decreased by 33% and still achieve a focused ion beam. In some tests, at an RF power of 1200W, the voltage applied to the extraction electrode 130 may be equal to the voltage applied to the workpiece holder 150. However, if the RF power is increased, the voltage applied to the extraction electrode 130 may be made more negative than the workpiece holder 150 to achieve a focused ion beam. Similarly, if the RF power is decreased, the voltage applied to the extraction electrode 130 may be made less negative than the workpiece holder 150 to achieve a focused ion beam.

Second, the system of FIG. 1 may also be used to vary the mean angle of the ion beam 106. In one test, by making the voltage applied to the second extraction electrode portion 141100V more negative than the voltage applied to the first extraction electrode portion 131, the mean angle of the ion beam 106 was decreased by 5°. In another test using a different RF power and the same extraction voltage, by making the voltage applied to the first extraction electrode portion 13150V more negative than the voltage applied to the second extraction electrode portion 141, the mean angle of the ion beam 106 was increased by 5°.

Thus, the independently biased extraction electrode 130 allows degrees of freedom in selecting RF power, extraction voltage and mean tilt angle that are not previously possible.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. A semiconductor processing system, comprising:
a workpiece holder;
an ion source to generate a ribbon ion beam which is larger in a width direction than in a height direction, the ion source comprising an ion source chamber including an extraction plate having a slanted portion with an extraction aperture, wherein the slanted portion is not parallel to the workpiece holder when the workpiece holder is in a processing position;
an extraction electrode disposed outside the extraction aperture disposed between the extraction plate and the workpiece holder; and
an electrode power supply to bias the extraction electrode at a different voltage from the workpiece holder and the ion source chamber.

2. The semiconductor processing system of claim 1, wherein a voltage applied to the extraction electrode by the electrode power supply is between -10,000V and 2,000V.

3. The semiconductor processing system of claim 1, wherein the extraction electrode comprises a single component having an opening such that the ribbon ion beam passes therethrough.

4. The semiconductor processing system of claim 1, wherein the extraction electrode comprises a first extraction electrode portion and a second extraction electrode portion located on opposite sides of the extraction aperture in the height direction.

5. The semiconductor processing system of claim 1, wherein at least one power supply is used to create a voltage differential between the ion source chamber and the workpiece holder, wherein the voltage differential is referred to as an extraction voltage.

6. The semiconductor processing system of claim 5, further comprising an RF antenna in communication with at least one chamber wall of the ion source chamber, and a RF power supply to supply an RF power to the RF antenna.

7. A method of operating the semiconductor processing system of claim 6, comprising:
selecting an RF power to apply to the RF antenna;
selecting an extraction voltage; and
varying an output voltage of the electrode power supply until a focused ion beam is extracted from the extraction aperture.

8. A semiconductor processing system, comprising:
a workpiece holder;
an ion source to generate a ribbon ion beam which is larger in a width direction than in a height direction, the ion source comprising an ion source chamber including an extraction plate having a slanted portion with an extraction aperture, wherein the slanted portion is not parallel to the workpiece holder when the workpiece holder is in a processing position;
an extraction electrode disposed outside the extraction aperture disposed between the extraction plate and the workpiece holder, the extraction electrode comprising a first extraction electrode portion and a second extraction electrode portion located on opposite sides of the extraction aperture in the height direction;
a first electrode power supply to bias the first extraction electrode portion; and
a second electrode power supply to bias the second extraction electrode portion.

9. The semiconductor processing system of claim 8, wherein a voltage applied to the first extraction electrode portion by the first electrode power supply is between -10,000V and 2,000V.

10. The semiconductor processing system of claim 8, wherein a voltage applied to the second extraction electrode portion by the second electrode power supply is between -10,000V and 2,000V.

11. The semiconductor processing system of claim 8, wherein at least one power supply is used to create a voltage differential between the ion source chamber and the workpiece holder, wherein the voltage differential is referred to as an extraction voltage.

12. The semiconductor processing system of claim 11, further comprising an RF antenna in communication with at least one chamber wall of the ion source chamber, and a RF power supply to supply an RF power to the RF antenna.

13. A method of operating the semiconductor processing system of claim 12, comprising:
selecting an RF power to apply to the RF antenna;
selecting an extraction voltage; and
varying output voltages of the first electrode power supply and the second electrode power supply until a focused ion beam is extracted from the extraction aperture.

14. The method of claim 13, wherein the varying also adjusts a mean angle of the focused ion beam.

15. A method of operating the semiconductor processing system of claim 13, wherein the outputs of the first electrode power supply and the second electrode power supply are maintained at a same voltage as the ribbon ion beam is being focused, and the method further comprising:
measuring a mean angle of the focused ion beam; and
creating a voltage differential between the first extraction electrode portion and the second extraction electrode portion to adjust the mean angle to achieve a desired tilt angle.

16. A method of operating the semiconductor processing system of claim 12, further comprising:
measuring a mean angle of the ribbon ion beam; and
creating a voltage differential between the first extraction electrode portion and the second extraction electrode portion to adjust the mean angle to achieve a desired tilt angle.
